(19) United States
(12) Patent Application Publication
(10) Pub. No.: US 2022/0344163 A1
(43) Pub. Date: Oct. 27, 2022

(54) GRINDING METHOD

(71) Applicant: DISCO CORPORATION, Tokyo (JP)

(72) Inventor: Yoshikazu SUZUKI, Tokyo (JP)

(21) Appl. No.: 17/658,132

(22) Filed: Apr. 6, 2022

(30) Foreign Application Priority Data
Apr. 27, 2021 (JP) 2021-074620

(51) Int. Cl. H01L 21/304; B24B 7/22; B24B 41/047

(52) U.S. Cl. CPC H01L 21/304; B24B 7/22; B24B 41/047

(57) ABSTRACT

A grinding method of grinding a first surface side of a wafer having an oxide film on the first surface includes a first grinding step of putting a grinding unit into grinding feeding while rotating a grinding wheel, rotating a chuck table holding under suction a second surface side at a first rotating speed, thereby causing lower surfaces of grindstones to break through the oxide film, then scraping off the oxide film by side surfaces of the grindstones, and forming a step in a circumferential direction of the wafer, a grinding unit raising step of spacing the grindstones from the wafer, and a second grinding step of putting the grinding unit into grinding feeding while rotating the grinding wheel to grind the wafer, in a state in which the chuck table holding under suction a second surface is rotated at a second rotating speed higher than the first rotating speed.

### BACKGROUND OF THE INVENTION

### Field of the Invention

The present invention relates to a grinding method for grinding a wafer with an oxide film.

### Description of the Related Art

In a manufacturing process of semiconductor device chips, for forming semiconductor device chips having a predetermined thickness, a back surface side on a side opposite to a front surface side of a wafer formed with devices is ground by a grinding apparatus to thin the wafer (see, for example, Japanese Patent Laid-open No. 2009-90389).

The grinding apparatus includes a disk-shaped chuck table rotatable around a predetermined rotational axis, and a grinding unit having a spindle disposed substantially parallel to a vertical direction is disposed above the chuck table. To a lower end portion of the spindle, an annular grinding wheel is mounted through a disk-shaped mount. The grinding wheel has a base, and a plurality of grindstones disposed along a circumferential direction of the base on one surface of the base.

To grind the wafer, the front surface side of the wafer is under suction held by the chuck table such that the back surface side of the wafer is exposed to the upper side. Then, the spindle and the chuck table are respectively rotated, and the grinding unit is put into downward grinding feeding, to thereby grind the back surface side of the wafer.

Incidentally, an oxide film may be formed on the back surface side of the wafer. When the oxide film is ground, conditions of the grindstones is liable to be degraded. For example, dulling, shedding, clogging, and the like of the grindstones are liable to occur.

### SUMMARY OF THE INVENTION

The present invention has been made in consideration of such problems. It is an object to remove an oxide film while reducing the degree of degradation of conditions of grindstones and to thin a wafer.

In accordance with an aspect of the present invention, there is provided a grinding method of grinding a first surface side of a wafer having an oxide film on the first surface by use of a grinding unit having a grinding wheel mounted therein, the grinding wheel having a plurality of grindstones disposed in an annular pattern, the grinding method including a first grinding step of putting the grinding wheel into grinding feeding while rotating the grinding wheel, rotating a chuck table holding under suction a second surface side located on a side opposite to the first surface at a first rotating speed, thereby causing lower surfaces of the grindstones to break through the oxide film, then scraping off the oxide film by side surfaces of the grindstones, and forming a step in a circumferential direction of the wafer on the first surface side, a raising step of raising the grinding unit to space the grindstones from the wafer, after the first grinding step, and a second grinding step of putting the grinding unit into grinding feeding to grind the wafer while rotating the grinding wheel in a state in which the chuck table holding under suction the second surface is rotated at a second rotating speed higher than the first rotating speed, after the raising step.

Preferably, the first rotating speed of the chuck table in the first grinding step is 10 rpm to 60 rpm. In addition, the second rotating speed of the chuck table in the second grinding step is 100 rpm to 500 rpm.

In the grinding method according to one mode of the present invention, the first surface side of the wafer having the oxide film on the first surface is ground. Therefore, first, grinding feeding of the grinding unit is conducted while rotating the grinding wheel, and the chuck table holding under suction the second surface side of the wafer is rotated at the first rotating speed, whereby the lower surfaces of the grindstones break through the oxide film, the oxide film is then scraped off by the side surfaces of the grindstones, and the step in the circumferential direction of the wafer is formed on the first surface side (first grinding step). Therefore, as compared to the case where the oxide film is scraped off mainly by the lower surfaces of the grindstones by rotating the chuck table at such a high rotating speed that the step in the circumferential direction of the wafer is not formed, the oxide film can be removed while reducing the degree of degradation of the conditions of the lower surfaces of the grindstones.

After the first grinding step, the grinding unit is raised, whereby the grindstones are spaced from the wafer (raising step). After the raising step, in a state in which the chuck table is rotated at the second rotating speed higher than the first rotating speed, the grinding wheel is rotated, and simultaneously, the grinding unit is put into grinding feeding to grind the wafer to a predetermined thickness (second grinding step). By grinding feeding the grinding unit after the raising step to perform the second grinding step, by use of both the lower surfaces and the side surfaces of the grindstones, not by use of only the side surfaces of the grindstones, the first surface side can be ground. Particularly, in the second grinding step, since the second rotating speed is higher than the first rotating speed, the back surface side of the wafer inclusive of the step can be gradually ground.

Therefore, as compared to the case where the chuck table is not rotated and a groove deeper than the thickness of the oxide film is formed on the back surface side before rotation of the chuck table is started in a state in which the grindstones are disposed in the groove to grind the back surface side inclusive of the oxide film at a stroke, a load on the grindstones is reduced, and therefore, a wearing amount of the grindstones can be reduced. In addition, in the first grinding step, the conditions of the lower surfaces of the grindstones are comparatively favorably maintained as compared to the case where the oxide film is scraped off by the lower surfaces of the grindstones, in the second grinding step, the lower surfaces of the grindstones can sufficiently contribute to grinding.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a grinding apparatus;

FIG. 2 is a flow chart of a grinding method;

FIG. 3 is a diagram depicting a first grinding step;

FIG. 4A is a top plan view of a wafer when grindstones break through an oxide film;

FIG. 4B is a side view of FIG. 4A;

FIG. 5A is a top plan view at a time at which a first grinding step has been completed;

FIG. 5B is a side view of FIG. 5A;

FIG. 6 is a diagram depicting a raising step;

FIG. 7 is a diagram depicting a second grinding step;

FIG. 8A is a top plan view of the wafer at a time of starting the second grinding step;

FIG. 8B is a side view of FIG. 8A;

FIG. 9A is a diagram depicting a manner in which the grindstones collide against an upper end part of a step in a first turn;

FIG. 9B is a diagram depicting a manner in which the grindstones collide against the upper end part of the step in a second turn;

FIG. 9C is a diagram depicting a manner in which the grindstones collide against the upper end part of the step in a third turn; and

FIG. 9D is a diagram depicting a manner of spark out.

### DETAILED DESCRIPTION OF THE PREFERRED EMBODIMENT

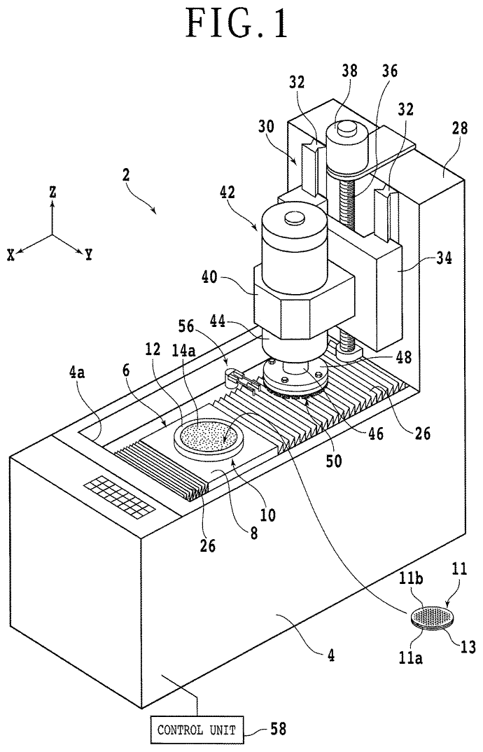

An embodiment according to one mode of the present invention will be described referring to the attached drawings. First, a grinding apparatus 2 used in the present embodiment will be described. FIG. 1 is a partially sectional side view of the grinding apparatus 2. In FIG. 1, a part of constituent elements of the grinding apparatus 2 is indicated by functional blocks. In addition, an X-axis direction, a Y-axis direction, and a Z-axis direction (up-down direction, a grinding feeding direction) are mutually orthogonal directions. The grinding apparatus 2 has a base 4 on which each constituent element is provided. On an upper surface of the base 4, an opening 4a having a longitudinal part along the X-axis direction is formed.

Inside the opening 4a, a ball screw type X-axis direction moving mechanism 6 is disposed. The X-axis direction moving mechanism 6 has a pair of guide rails (not illustrated) disposed along the X-axis direction. Between the pair of guide rails, a screw shaft (not illustrated) is disposed along the X-axis direction. To one end of the screw shaft, a pulse motor (not illustrated) for rotating the screw shaft is connected.

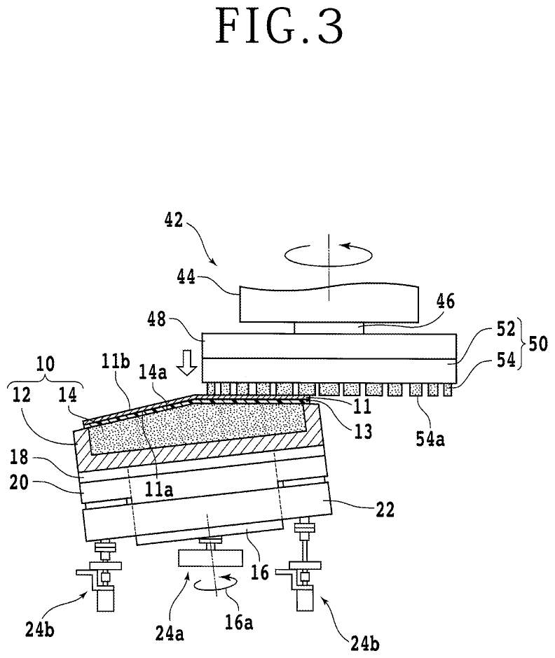

A nut section (not illustrated) provided on a lower surface side of an X-axis direction moving table (not illustrated) is connected to the screw shaft in a rotatable manner through a ball (not illustrated). When the screw shaft is rotated by the pulse motor, the X-axis direction moving table is moved along the X-axis direction. On the X-axis direction moving table, a rotational drive source (not illustrated) such as a motor is provided. The rotational drive source rotates a chuck table 10 provided on a table cover 8 around a predetermined rotational axis 16 (see FIG. 3).

Here, a configuration of the chuck table 10 will be described with reference to FIG. 3. The chuck table 10 has a disk-shaped frame body 12 formed of a ceramic. The frame body 12 is formed with a disk-shaped recess. At a bottom portion of the recess, an end portion of a suction passage (not illustrated) is exposed. The other end portion of the suction passage is connected to a suction source (not illustrated) such as an ejector. A disk-shaped porous plate 14 is fixed to the recess. An upper surface of the porous plate 14 is formed in the shape of a cone in which a central part is slightly projected as compared with a peripheral part. When the suction source is operated, a negative pressure is transmitted through the suction passage, and a negative pressure is generated on the upper surface of the porous plate 14.

The upper surface of the porous plate 14 and an upper surface of the frame body 12 are substantially flush and functions as a holding surface 14a holding under suction a wafer 11 (see FIG. 1). To a lower portion of the chuck table 10, a rotational axis 16 of a rotational drive source (not illustrated) is connected. The chuck table 10 is supported by an annular table base 22 through an annular bearing 18 and a support plate 20. In addition, on a lower surface side of the table base 22, a fixed support section 24a and two movable support sections 24b are provided. At least one movable support section 24b is contracted and expanded in the Z-axis direction, whereby the inclination of the table base 22 is adjusted. As a result, the inclination of the chuck table 10 is adjusted such that a part of the holding surface 14a and a grinding surface of grindstones 54 become substantially parallel.

Here, returning to FIG. 1, other constituent elements of the grinding apparatus 2 will be described. On both sides in the table cover 8, bellows-like covers 26 capable of contracting and expanding in the X-axis direction are provided. On one side (rear side) in the X-axis direction of the opening 4a, a rectangular parallelepiped support structure 28 extending upward is provided. On the front surface side of the support structure 28, a Z-axis direction moving mechanism 30 is provided. The Z-axis direction moving mechanism 30 includes a pair of Z-axis guide rails 32 disposed along the Z-axis direction. To the pair of Z-axis guide rails 32, a Z-axis direction moving plate 34 is attached in the slidable manner along the Z-axis direction.

On the rear surface side (back surface side) of the Z-axis direction moving plate 34, a nut section (not illustrated) is provided. To the nut section, a screw shaft 36 disposed along the Z-axis direction is connected in a rotatable manner through a ball (not illustrated). A Z-axis pulse motor 38 is connected to an upper end portion of the screw shaft 36 in the Z-axis direction. When the screw shaft 36 is rotated by the Z-axis pulse motor 38, the Z-axis direction moving plate 34 is moved in the Z-axis direction along the Z-axis guide rails 32.

On a front surface side of the Z-axis direction moving plate 34, a support member 40 is provided. The support member 40 supports the grinding unit 42. The grinding unit 42 has a cylindrical spindle housing 44 whose height is disposed substantially parallel to the Z-axis direction. In the spindle housing 44, a part of a cylindrical spindle 46 whose height is disposed substantially parallel to the Z-axis direction is accommodated in a rotatable manner. At an upper end portion of the spindle 46, a motor (not illustrated) for rotating the spindle 46 is provided.

A lower end portion of the spindle 46 is exposed from the spindle housing 44, and an upper surface side of a disk-shaped wheel mount 48 formed of a metal material such as stainless steel is fixed to the lower end portion of the spindle 46. To a lower surface of the wheel mount 48, an annular grinding wheel 50 substantially equal in diameter to the wheel mount 48 is mounted.

As depicted in FIG. 3, the grinding wheel 50 has an annular wheel base 52 formed of a metal material such as an aluminum alloy. On a lower surface side of the wheel base 52, a plurality of grindstones 54 are disposed along the circumferential direction of the wheel base 52 in an annular pattern and at substantially regular intervals. Lower surfaces 54a of the plurality of grindstones 54 are located at substantially the same height position in the Z-axis direction, and constitute a grinding surface for grinding the wafer 11.

To grind the wafer 11, first, the chuck table 10 is disposed at a position (conveying-in/conveying-out position) depicted in FIG. 1, and the wafer 11 is held under suction by the holding surface 14a. Next, the chuck table 10 is moved to a grinding position located below the grinding unit 42. In the vicinity of the grinding position, a grinding water supply nozzle (not illustrated) for supplying grinding water such as pure water to a contact region (processing region) of the grindstones 54 and the back surface 11b at the time of grinding is disposed. In addition, at a position adjacent to the chuck table 10 disposed at the grinding position in the Y-axis direction, a height gauge 56 for measuring the thickness of the wafer 11 is provided.

Operations of the X-axis direction moving mechanism 6, the rotational drive source, the suction source, the Z-axis direction moving mechanism 30, the grinding unit 42, the grinding water supply nozzle, the height gauge 56, and the like are controlled by a control unit 58 of the grinding apparatus 2. The control unit 58 includes, for example, a computer including a processor (processing device) represented by a central processing unit (CPU), a main storage device such as a dynamic random access memory (DRAM), and au auxiliary storage device such as flash memory. The auxiliary storage device stores software. By operating the processing device and the like according to the software, the functions of the control unit 58 are realized. In addition, the auxiliary storage device also stores a predetermined program for carrying out the grinding method described below.

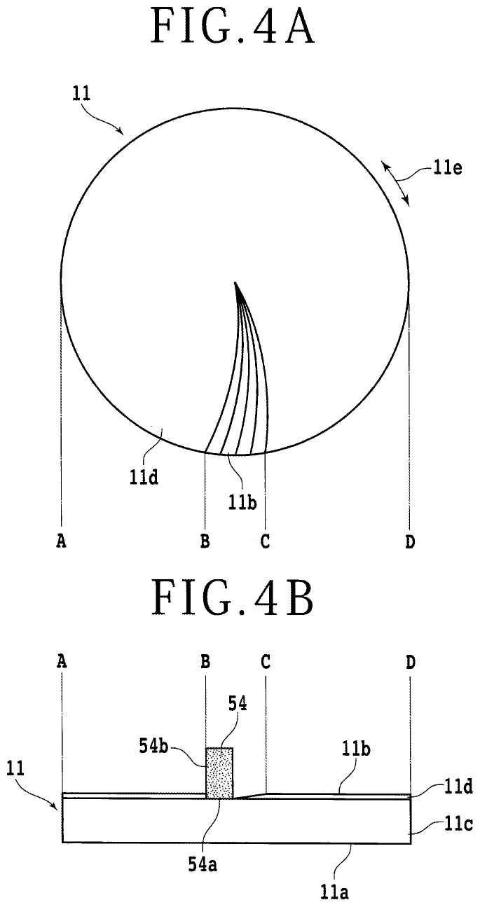

The wafer 11 is a disk-shaped silicon wafer having a predetermined diameter (for example, approximately 200 mm), and has a single crystal layer 11c (see FIG. 4B). Note that a kind, a material, a size, a shape, a structure, and the like of the wafer 11 are not limited. The wafer 11 may be a compound semiconductor other than silicon (GaN, SiC, etc.), or may be a wafer or a substrate formed of a ceramic, a metal, or the like. The wafer 11 has a front surface (second surface) 11a and a back surface (first surface) 11b located on a side opposite to the front surface 11a. The thickness of the wafer 11 is a predetermined value (for example, 725 μm) in the range of 200 μm to 800 μm.

On the front surface 11a, a plurality of division lines (streets) are set in a grid pattern. On the front surface 11a side in each rectangular region partitioned by the plurality of streets, a device (not illustrated) such as an integrated circuit (IC) or a large scale integration (LSI) is formed. On the front surface 11a side of the wafer 11, a resin-made protective tape 13 is attached for the purpose of protecting the devices. Note that a kind, an amount, a shape, a structure, a size, a layout, and the like of the devices formed on the wafer 11 are not limited. The devices may not be formed on the wafer 11.

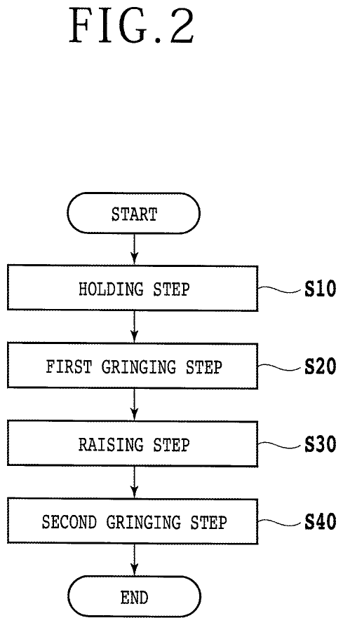

The wafer 11 is a wafer with an oxide film, on the whole body of the back surface 11b side, an oxide film 11d (for example, a thermal oxide film of silicon) having a thickness on the order of 1 μm is provided (see FIG. 4B). To grind the back surface 11b side, first, the oxide film 11d is ground, and when the oxide film 11d is ground, the conditions of the grindstones 54 is liable to be degraded. For example, dulling, shedding, clogging, and the like of the grindstones 54 are liable to occur. In the present embodiment, for removing the oxide film 11d and thinning the wafer 11 while reducing the degree of degradation of the conditions of the grindstones 54, the back surface 11b side is ground according to the procedure depicted in FIG. 2.

FIG. 2 is a flow chart of the grinding method in the present embodiment. First, the front surface 11a side is held under suction by the holding surface 14a such that the back surface 11b is exposed to the upper side (holding step S10). In this instance, the wafer 11 is deformed after the shape of the holding surface 14a. Note that the chuck table 10 is adjusted in its inclination such that a part of the holding surface 14a becomes substantially parallel to the grinding surfaces of the grindstones 54 (see FIG. 3). After the holding step S10, a first grinding step S20 is performed.

FIG. 3 is a diagram depicting the first grinding step S20. In the first grinding step S20, the spindle 46 is rotated at high speed (in this example, 4,000 rpm) to thereby rotate the grinding wheel 50, and the grinding unit 42 is put into downward grinding feeding. In this instance, grinding water is supplied from the grinding water supply nozzle to a processing region, and the chuck table 10 is rotated at a first rotating speed 16a. The first rotating speed 16a is a predetermined value in the range of 10 rpm to 60 rpm, preferably 10 rpm to 30 rpm. The first rotating speed 16a in the present embodiment is 15 rpm. In addition, in the present embodiment, the thickness of the oxide film 11d is 1 μm, and the grinding feeding speed is 3 μm/s, so that the lower surfaces 54a break through the oxide film 11d in ⅓ second after the lower surfaces 54a makes contact with the oxide film 11d (see FIGS. 4A and 4B).

FIG. 4A is a top plan view of the wafer 11 at the time when the grindstones 54 break through the oxide film 11d, and FIG. 4B is a side view of FIG. 4A. A position A in FIG. 4A and a position A in FIG. 4B correspond to each other. The same applies to positions B, C, and D. Note that in FIG. 4B, the protective tape 13 is omitted. In other drawings, also, the protective tape 13 may be omitted.

Until the grindstones 54 break through the oxide film 11d, the oxide film 11d is ground mainly by the lower surfaces 54a of the grindstones 54. Then, when the grindstones 54 have broken through the oxide film 11d, the bottom surfaces of the grindstones 54 make contact with the single crystal layer 11c as depicted in FIG. 4B, and thereafter, the oxide film 11d is removed mainly by the side surfaces 54b of the grindstones 54. Therefore, as compared to the case where the chuck table 10 is rotated at a comparatively high speed (for example, 300 rpm) and the oxide film 11d is scraped off mainly by the lower surfaces 54a of the grindstones 54, the oxide film 11d can be removed while reducing the degree of degradation of the conditions of the lower surfaces 54a of the grindstones 54.

To completely remove the oxide film 11d, the chuck table 10 has to be rotated one revolution or more. Specifically, in a case where the first rotating speed 16a is 15 rpm, when grinding is conducted for four seconds after the lower surfaces 54a make contact with the oxide film 11d, the chuck table 10 is rotated one revolution (because 60/15 s=4 s), and the grindstones 54 advances downward by 12 μm (=3 μm/s×4 s). However, as depicted in FIG. 4B, cutting residue of the oxide film 11d is generated from the start of grinding to the time when the grindstones 54 break through the oxide film 11d, the oxide film 11d cannot be completely removed from the back surface 11b side by only rotating the chuck table 10 just one revolution.

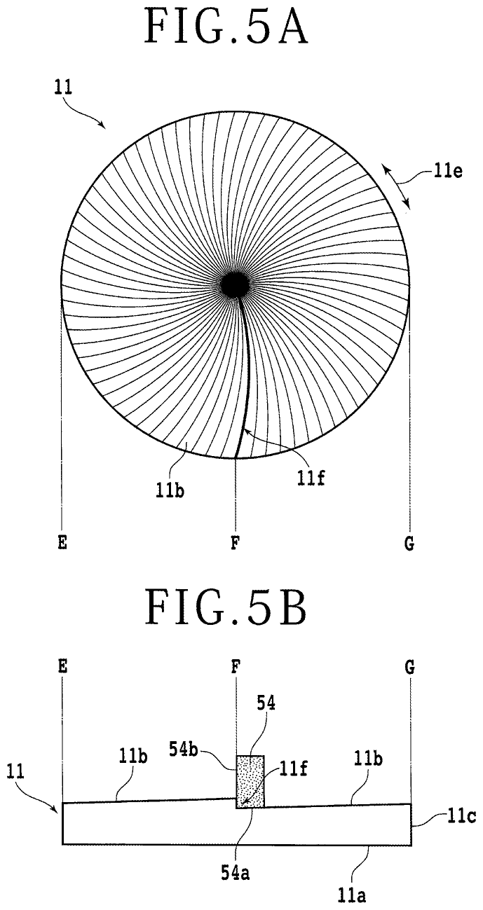

In a case where the grinding feeding speed of the grinding unit 42 is 3 μm/s, ⅓ second is taken from the start of grinding to the time when the grindstones 54 break through the oxide film 11d, in the first grinding step S20, the back surface 11b side is ground for ⅓ second or more in addition to four seconds (for example, a total of 4.4 seconds). In this way, the oxide film 11d is completely scraped off. In this instance, in the circumferential direction 11e of the wafer 11, a step 11f (see FIGS. 5A and 5B) is formed. FIG. 5A is a top plan view of the wafer 11 at the time of completion of the first grinding step S20, and FIG. 5B is a side view of FIG. 5A. A position E of FIG. 5A and a position E of FIG. 5B correspond to each other. The same applies also to positions F and G.

In the case where the grinding feeding speed of the grinding unit 42 is constant, a depth of the step 11f is determined by the rotating speed of the chuck table 10. For example, in a case where the chuck table 10 is rotated at 10 rpm, the chuck table 10 is rotated one revolution in six seconds (=60/10 s), during this revolution, the step 11f with a depth of 18 μm (=6 s×3 μm/s) is formed on the back surface 11b side. In addition, in a case where the chuck table 10 is rotated at 30 rpm, the chuck table 10 is rotated one revolution in two seconds (=60/30 s), during this revolution, the step 11f with a depth of 6 μm (=2 s×3 μm/s) is formed on the back surface 11b side.

In this way, due to the first rotating speed 16a which is a comparatively low speed, for example, the step 11f with a predetermined depth of 5 μm to 20 μm is formed. The depth of the step 11f in the present embodiment is approximately 13 μm (=3 μm/s×4.4 s). As depicted in FIGS. 5A and 5B, on the back surface 11b side of the wafer 11 at the time of completion of the first grinding step S20, one spiral step 11f is formed. In FIG. 5A, a thick line is applied to a region corresponding to the step 11f, and a thin line is applied to a saw mark.

Incidentally, in a case where the oxide film 11d is scraped off mainly by the lower surfaces 54a of the grindstones 54 by rotating the chuck table 10 at such a high rotating speed that the step 11f having the abovementioned predetermined depth in the circumferential direction 11e is not formed, the conditions of the lower surfaces 54a are liable to be degraded. In the first grinding step S20 of the present embodiment, as compared to the case where the chuck table 10 is rotated at such a high speed that the step 11f is not formed, the oxide film 11d can be removed while reducing the degree of degradation of the conditions of the lower surfaces 54a.

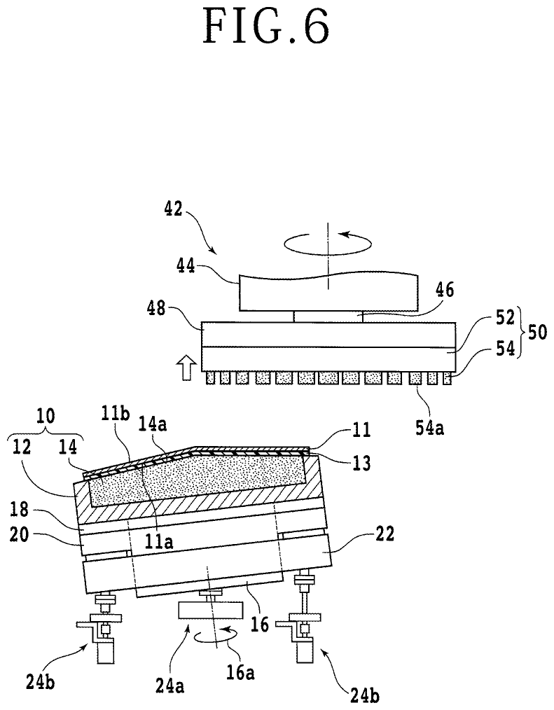

After completion of the first grinding step S20, the grinding unit 42 is raised, whereby the grindstones 54 are spaced from the back surface 11b (raising step S30). More specifically, the grinding unit 42 is raised such that the lower surfaces 54a are located above the maximum position of the back surface lib. FIG. 6 is a diagram depicting the raising step S30. After the raising step S30, the chuck table 10 is rotated at a second rotating speed 16b higher than the first rotating speed 16a, to perform a second grinding step S40.

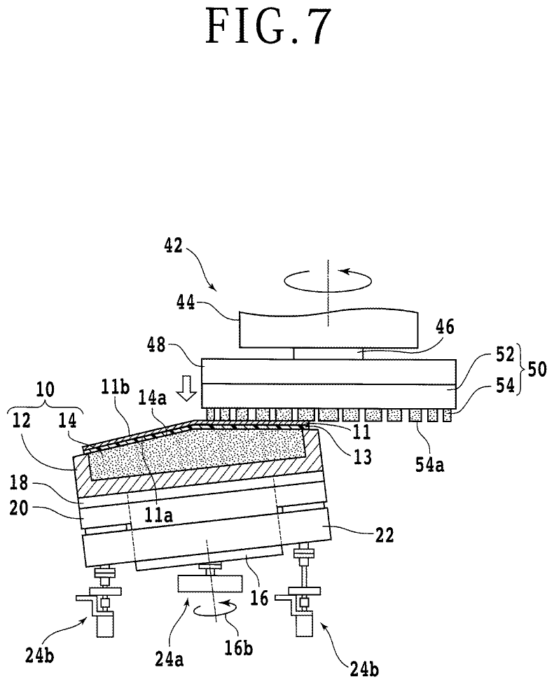

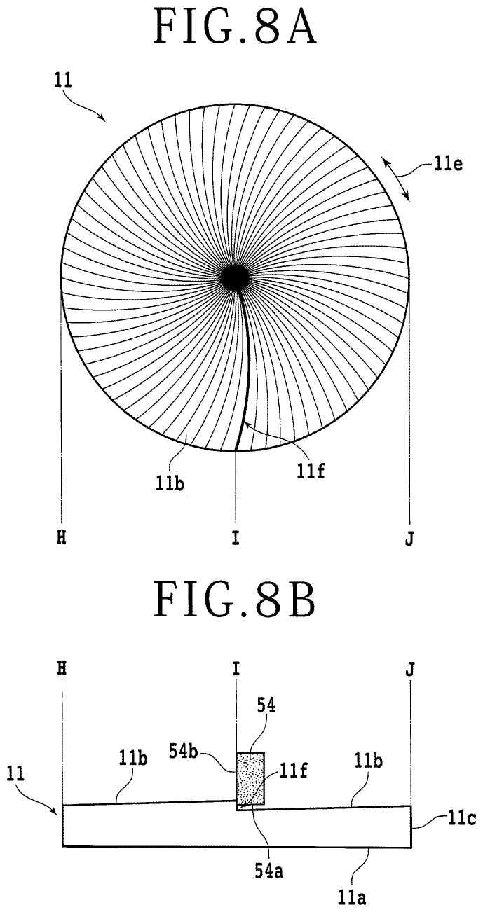

FIG. 7 is a diagram depicting the second grinding step S40. FIG. 8A is a top plan view of the wafer 11 at the start of the second grinding step S40, and FIG. 8B is a side view of FIG. 8A. A position H of FIG. 8A and a position H of FIG. 8B correspond to each other. The same applies also to positions I and J. By performing grinding feeding of the grinding unit 42 after the raising step S30 to perform the second grinding step S40, by use of both the lower surfaces 54a and the side surfaces 54b of the grindstones 54, not by use of the side surfaces 54b of the grindstones 54 only, the back surface 11b side of the wafer 11 can be ground.

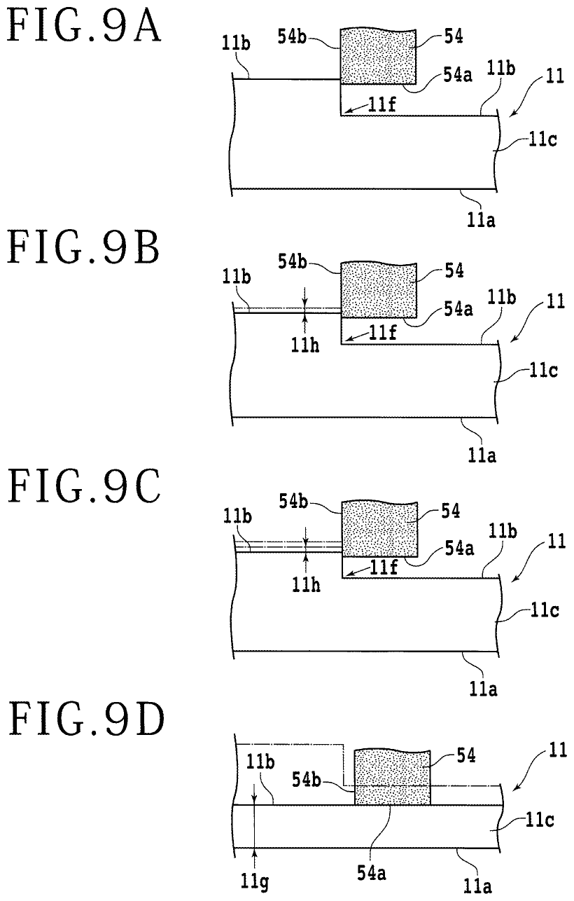

In the second grinding step S40, in a state in which the chuck table 10 is rotated at the second rotating speed 16b, the grinding unit 42 is put into grinding feeding while the grinding wheel 50 is rotated, to grind and thin the wafer 11 to a predetermined thickness 11g (see FIG. 9D). Note that the rotating speed of the spindle 46 in the present embodiment is not changed from the first grinding step S20 and the raising step S30, but is maintained at 4,000 rpm, and the rotating speed of the spindle 46 may be set appropriately as long as it is sufficiently higher than the rotating speed of the chuck table 10.

The second rotating speed 16b is a predetermined value in the range of 100 rpm to 500 rpm, preferably 200 rpm to 400 rpm. The second rotating speed 16b of the present embodiment is 300 rpm. Therefore, it is necessary for the chuck table 10 to take 0.2 second (=(60/300) s) for one revolution. In addition, since the grinding speed is 3 μm/s, during 0.2 second, the grinding unit 42 is put into downward grinding feeding by 0.6 μm (=3 μm/s×0.2 s).

FIG. 9A is a diagram depicting a manner in which the side surface 54b of the grindstones 54 collides against an upper end portion of the step 11f in a first turn, and FIG. 9B is a diagram depicting a manner in which the side surface 54b of the grindstones 54 collide against the upper end portion of the step 11f in a second turn. After the side surface 54b collides against the upper end portion of the step 11f in the first turn until the side surface 54b collides against the upper end portion of the step 11f in the second turn, an upper portion on the back surface 11b side is ground and removed by 0.6 μm (predetermined thickness 11h).

FIG. 9C is a diagram depicting a manner in which the side surface 54b of the grindstones 54 collides against the upper end portion of the step 11f in a third turn. After the side surface 54b collides against the upper end portion of the step 11f in the second turn until the side surface 54b collides against the upper end portion of the step 11f in the third turn, an upper portion on the back surface 11b side is similarly removed by the predetermined thickness 11h. Particularly, in the second grinding step S40, since the second rotating speed 16b is higher than the first rotating speed 16a, the back surface 11b side of the wafer 11 including the step 11f can be gradually ground.

Therefore, as compared to the case where the chuck table 10 is not rotated and a groove (not illustrated) deeper than the thickness of the oxide film 11d is formed on the back surface 11b side before rotation of the chuck table 10 is started in a state in which the grindstones 54 are disposed in the groove to grind the back surface 11b side including the oxide film 11d at a stroke, a load on the grindstones 54 is reduced, and therefore, a wearing amount of the grindstones 54 can be reduced. In addition, in the first grinding step S20, as compared to the case of scraping off the oxide film 11d mainly by the lower surfaces 54a of the grindstones 54, the conditions of the lower surfaces 54a of the grindstones 54 are comparatively favorably maintained, so that the lower surfaces 54a of the grindstones 54 sufficiently contribute to grinding in the second grinding step S40.

In the second grinding step S40, after the back surface 11b side is ground for a predetermined period of time, grinding feeding is stopped while the rotating speeds of the spindle 46 and the chuck table 10 are maintained. In other words, the grinding feeding speed is set to 0 μm/s. As a result, the back surface 11b side is ground to a predetermined thickness 11g (what is generally called spark out). FIG. 9D is a diagram depicting the manner of spark out in the second grinding step S40. The back surface 11b after the spark out becomes flatter as compared to the case where the second grinding step S40 is finished without performing the spark out.

As compared to the case of scraping off the oxide film 11d mainly by the lower surfaces 54a of the grindstones 54 by rotating the chuck table 10 at such a high rotating speed that the step 11f having the abovementioned predetermined depth in the circumferential direction 11e is not formed, in the first grinding step S20 of the present embodiment, the oxide film 11d can be removed while reducing the degree of degradation of the conditions of the lower surfaces 54a of the grindstones 54. In addition, after the first grinding step S20, the raising step S30 is conducted, and then the second grinding step S40 is performed. As a result, by use of both the lower surfaces 54a and the side surfaces 54b of the grindstones 54, not by use of the side surfaces 54b of the grindstones 54 only, the back surface 11b side can be ground.

Particularly, in the second grinding step S40, since the second rotating speed 16b is higher than the first rotating speed 16a, the back surface 11b side of the wafer 11 inclusive of the step 11f can be gradually ground. Therefore, as compared to the case where the chuck table 10 is not rotated and a groove deeper than the thickness of the oxide film 11d is formed on the back surface 11b side before rotation of the chuck table 10 is started in a state in which the grindstones 54 are disposed in the groove to grind the back surface 11b side inclusive of the oxide film 11d at a stroke, a load on the grindstones 54 is reduced, and a wearing amount of the grindstones 54 can be reduced.

In addition, in the first grinding step S20, the conditions of the lower surfaces 54a of the grindstones 54 are comparatively favorably maintained as compared to the case of scraping off the oxide film 11d mainly by the lower surfaces 54a of the grindstones 54, so that the lower surfaces 54a of the grindstones 54 can sufficiently contribute to grinding in the second grinding step S40.

Other than the above, the structure, method, and the like according to the above embodiment can be modified appropriately insofar as the modifications do not depart from the scope of the object of the present invention. The grinding apparatus 2 of the above embodiment is of what is generally called manual type, but may be of an automatic grinding system having a rough grinding unit and a finish grinding unit. Besides, an automatic grinding and polishing system having a rough grinding unit, a finish grinding unit and a polishing unit may also be adopted.

The present invention is not limited too the details of the above described preferred embodiment. The scope of the invention is defined by the appended claims and all changes and modifications as fall within the equivalence of the scope of the claims are therefore to be embraced by the invention.

What is claimed is:

1. A grinding method of grinding a first surface side of a wafer having an oxide film on the first surface by use of a grinding unit having a grinding wheel mounted therein, the grinding wheel having a plurality of grindstones disposed in an annular pattern, the grinding method comprising:
a first grinding step of putting the grinding wheel into grinding feeding while rotating the grinding wheel, rotating a chuck table holding under suction a second surface side located on a side opposite to the first surface at a first rotating speed, thereby causing lower surfaces of the grindstones to break through the oxide film, then scraping off the oxide film by side surfaces of the grindstones, and forming a step in a circumferential direction of the wafer on the first surface side;
a raising step of raising the grinding unit to space the grindstones from the wafer, after the first grinding step; and
a second grinding step of putting the grinding unit into grinding feeding to grind the wafer while rotating the grinding wheel in a state in which the chuck table holding under suction the second surface is rotated at a second rotating speed higher than the first rotating speed, after the raising step.

2. The grinding method according to claim 1,
wherein the first rotating speed of the chuck table in the first grinding step is 10 rpm to 60 rpm.

3. The grinding method according to claim 1,
wherein the second rotating speed of the chuck table in the second grinding step is 100 rpm to 500 rpm.
